(19) United States
(12) Patent Application Publication
(10) Pub. No.: US 2007/0037303 A1
(43) Pub. Date: Feb. 15, 2007

(54) Apparatus and method of illuminating the surface of a wafer in a wafer inspection system

(75) Inventor: Detlef Hogenkamp, Wetzlar (DE)

Correspondence Address: SIMPSON & SIMPSON, PLLC, 5555 MAIN STREET, WILLIAMSVILLE, NY, 14221-5406, US

(73) Assignee: Vistec Semiconductor Systems GmbH, Wetzlar (DE)

(21) Appl. No.: 11/502,152

(22) Filed: Aug. 10, 2006

(30) Foreign Application Priority Data
Aug. 11, 2005 (DE) 10 2005 038 332.7

(51) Int. Cl. H01L 21/66

(52) U.S. Cl. 438/16

(57) ABSTRACT

An apparatus for illuminating the surface of a wafer in a wafer inspection system, comprising a first flash source for emitting a first light beam and a second flash source for emitting a second light beam, a redirecting optics and a control means, wherein the flash sources are arranged for emitting towards the redirecting optics, the control means alternately triggers the flash sources, and the redirecting optics redirects the two light beams into the same beam path upstream of the wafer.

### CROSS REFERENCE TO RELATED APPLICATIONS

This patent application Claims priority of German Patent Application No. 10 2005 038 332.7, filed on Aug. 11, 2005, which application is incorporated herein by reference.

### FIELD OF THE INVENTION

The present invention relates to an apparatus for illuminating the surface of a wafer in a wafer inspection system. The present invention also relates to a method of illuminating the surface of a wafer in a wafer inspection system.

### BACKGROUND OF INVENTION

Apparatuses and/or methods of the above type are well known. In these apparatuses a wafer is illuminated and an image is taken of the illuminated wafer from which information is obtained about any defects on the wafer surface. The illumination is usually based on a flash source, the flash illumination of which is passed to the illumination optics upstream of the wafer via an optical waveguide. The flashing frequency, the imaging frequency and the intervals of movements of the wafer for imaging of each new SAW (scanning area window) are adjusted with respect to each other. The speed of inspection is therefore determined by the above-mentioned frequency. The maximum frequency herein depends on the maximum frequency of the flash device, which can only generate a certain number of flashes per time unit with sufficient flash power. This is why the inspection speed of wafer inspection depends on the frequency of the flash device.

### SUMMARY OF THE INVENTION

It is therefore an object of the present invention to further develop an apparatus and a method of the initially described type in such a way that the processing speed during wafer inspection is increased.

The object is solved by an apparatus for illuminating the surface of a wafer in a wafer inspection system, comprising a first flash source for emitting a first light beam and a second flash source for emitting a second light beam at a maximum frequency, a redirecting optics and a control means, wherein the flash sources are configured for emitting light toward the redirecting optics, the control means alternately triggers the flash sources with a certain frequency; and the redirecting optics redirects the two light beams into a common beam path upstream of the wafer. The object is as well solved by a method of illuminating the surface of a wafer, comprising the steps of:
rotating a rotary mirror so that the beam path of a first flash source is redirected into a common beam path,
triggering the first flash source,
illuminating the surface of the wafer with the light beam of the first flash source for inspecting the wafer,
rotating the rotary mirror so that the beam path of a second flash source is redirected into a common beam path,
triggering the second flash source,
illuminating the surface of the wafer with the light beam of the second flash source for inspecting the wafer.

According to the invention the above object is solved in an apparatus for illuminating the surface of a wafer in an inspection system, comprising a first flash source for emitting a first light beam and a second flash source for emitting a second light beam, a redirecting optics and a control means in that the flash sources are arranged for emitting towards the redirecting optics, and the control means alternately triggers the flash sources, and the redirecting optics redirects the two light beams into the same beam path upstream of the wafer.

The use of two flash sources of the same type for illuminating the surface of the wafer in the same way allows the flashing frequency to be doubled while the flash power remains the same. It has been found that the use of two flash sources of the same type of a certain flash power is cheaper than acquiring a flash source which would be capable of providing double the flashing frequency with the same power.

Preferably it is provided that the frequency of triggering is higher than half the maximum flashing frequency of the flash sources.

This makes sense since if the flashing frequency was lower a single flash source would suffice.

Suitably it is provided that the redirecting optics comprises a rotary mirror.

Advantageously it is provided that the rotary mirror is arranged in such a way that depending on the rotation angle it reflects the first or the second light beam every time into the same beam path. This is advantageous in that once the beam is in the same beam path and also on the surface of the wafer, it can hardly be decided which flash source each flash comes from. This means that a uniform measurement can be carried out irrespective of the flash source currently emitting the flash. It can be provided that the rotary mirror executes a reciprocating rotary motion between two extreme positions or to rotate via two intermediary positions.

Advantageously it is provided that the control means triggers the flash sources as a function of the rotary position of the rotary mirror so that the light beam of the triggered light source is reflected each time into the same beam path. This is how the flash and the rotary mirror are synchronized.

Advantageously it is provided that the rotary speed of the rotary mirror is sufficiently high for the frequency of triggering to be higher than half the maximum flashing frequency of the flash sources. The rotary speed of the rotary mirror is synchronized with the flashing frequency as mentioned above. Usually the suitable angular position of the rotary mirror triggers each light flash via the control means. The higher the rotary speed of the rotary mirror the higher therefore also the frequency of the triggering. A suitably high rotary speed of the rotary mirror thus enables a frequency of triggering which is higher than half the flashing frequency of the flash sources. The overall flashing frequency is therefore higher than the maximum flashing frequency of a single flash source while the flash power remains the same.

According to an embodiment of the present invention it is provided that the same beam path comprises a beam splitter. The beam splitter allows the flash sources together with the redirecting optics to be arranged at a suitable spatial position in the wafer inspection system and the light to be passed to the surface of the wafer in a simple way. Herein it is usually provided that the optical waveguide ends upstream of an optics directly upstream of the surface of the wafer.

According to a preferred embodiment of the invention it is provided that the two light beams impinge on the optical waveguide at the same angle. The same angle can be within a range of less than +/−10°, in particular less than +/−5°, in particular less than +/−2°, and in particular less than 1°. In particular, a mirrored angle can be interpreted as the same angle. It is thus ensured that the two light beams leave the optical waveguide, and pass into the optics upstream of the wafer surface, under the same conditions.

According to one embodiment it is provided that the flash sources and the redirecting optics have the same carrier, in particular the same housing. As a result of this arrangement a particularly compact and precise structure of the apparatus can be provided. In particular, the adjustment of the individual components is facilitated.

According to a preferred embodiment it is provided that the flash sources and the redirecting optics are configured as a module. The module is characterized in that it has a common carrier and/or a common housing which is releasably mounted in the wafer inspection system. This embodiment allows easy exchange and maintenance of the apparatus within the wafer inspection system.

According to the invention the originally mentioned object is solved in a method for illuminating the surface of a wafer in a wafer inspection system with the following method steps:
rotating a rotary mirror so that the beam path of a first flash source is redirected into a common beam path,
triggering the first flash source,
illuminating the surface of the wafer with the light beam of the first flash source for inspecting the wafer,
rotating the rotary mirror so that the beam path of a second flash source is redirected into a common beam path,
triggering the second flash source,
illuminating the surface of the wafer with the light beam of the second flash source for inspecting the wafer.

By alternately triggering the two flash sources and correspondingly rotating the rotary mirror so that the light flash of each flash source is redirected into a common beam path facilitates the use of two flash sources and therefore to increase the flashing frequency while the flash power remains the same.

Advantageously it is provided that each light beam is passed through an optical waveguide before it impinges on the surface of the wafer. As mentioned above the optical waveguide is the common beam path or a portion thereof.

### BRIEF DESCRIPTION OF THE DRAWINGS

The invention will be described in the following with reference to schematic representations of exemplary embodiments in more detail. The same reference numerals indicate the same elements throughout the individual figures, in which:

FIG. 1 shows an apparatus according to the present invention having a fixed-mirror system,

FIG. 2 shows an apparatus according to the present invention having a semi-transparent mirror,

FIG. 3 shows an apparatus according to the present invention with a rotary mirror, and

FIG. 4 shows the apparatus according to the present invention as shown in FIG. 3 with the beam path of the other flash source.

### DETAILED DESCRIPTION OF THE INVENTION

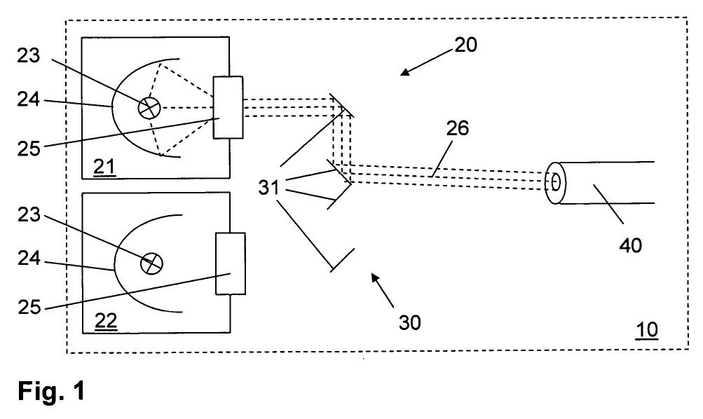

FIG. 1 shows the apparatus according to the present invention in a schematic representation of an illumination optics 20 with a first flash source 21, a second flash source 22 and a redirecting optics 30 within a wafer inspection system 10. First flash source 21, and second flash source 22, comprise a flash lamp 23, a reflector 24 and a beam optics 25. Light beam 26 emitted by the first flash source 21 is redirected by redirecting mirrors 31 of redirecting optics 30 in such a way that it impinges on the end of an optical waveguide 40 approximately vertically. Redirecting mirrors 31 of redirecting optics 30 are structured symmetrically so that they image a light beam of second flash source 22 onto the end of optical waveguide 40 also approximately vertically. In the present figure an operating state is shown in which the first flash source is triggered. Second flash source 22 is resting. When second flash source 22 is triggered the result is a mirror-symmetrical beam path leading to the end of optical waveguide 40.

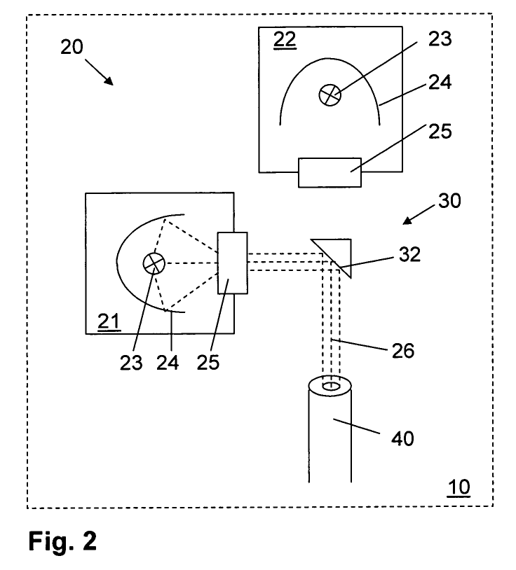

FIG. 2 shows an apparatus according to the present invention, similar to FIG. 1, wherein the two flash sources are arranged at an angle of 90° with respect to each other. Unlike FIG. 1, redirecting optics 30 is a semitransparent mirror 32. The semitransparent mirror is formed as a rectangular, isosceles triangular prism, the hypotenuse of which carries the semitransparent mirror. Semitransparent mirror 32 reflects a light beam of first flash source 21 at a 90° angle vertically onto the end of optical waveguide 40. When second flash source 22 is triggered the light beam enters the small side of the prism facing the second flash source in parallel into the prism, passes through the semitransparent mirror arranged at an angle of 45° essentially unaffected and also impinges vertically on the end of optical waveguide 40.

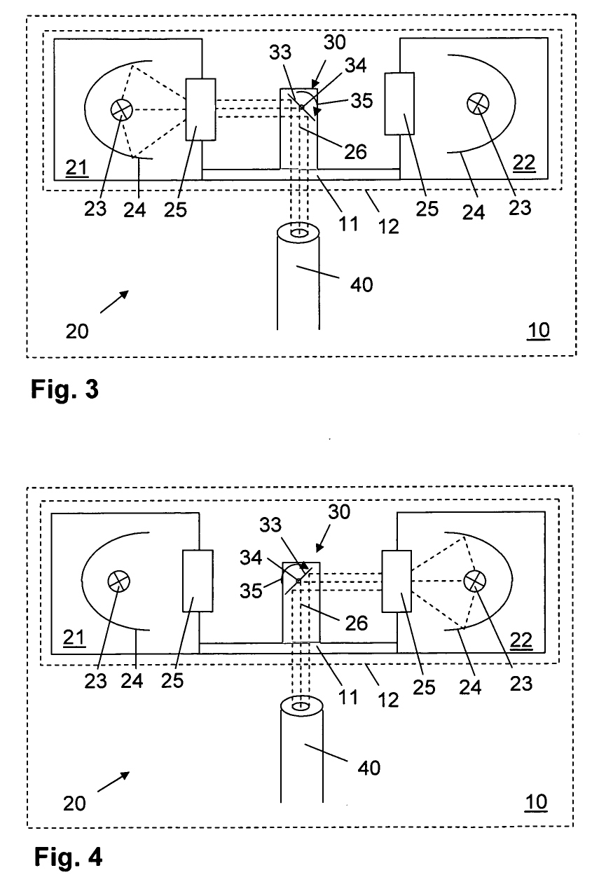

FIG. 3, in a schematic representation, shows the preferred embodiment of the apparatus according to the present invention. A first flash source 21 and a second flash source 22 are arranged facing each other across a redirecting optics 30. Redirecting optics 30 comprises a rotary mirror 33 which is provided for rotating in rotary direction 35 about a rotary axis 34. First flash source 21, second flash source 22 and rotary mirror 33 are mounted on a common carrier 11. The beam paths of the flash sources are opposed and parallel to each other and radiate towards the rotary mirror. The rotary mirror is a double-sided mirror, so that at a position of 45°, as shown, and at a position of 225°, it passes the light beam of first flash source 21 vertically on the end of optical waveguide 40, and in a position of 135° and 315° it passes the beam path of second flash source 22 vertically on the end of optical waveguide 40. Let it be assumed that the zero point of the angular measurements is the horizontal to the left of the centre of rotation, and the angular direction is the clockwise direction of rotation shown. First flash source 21 and second flash source 22, and redirecting optics 30 are arranged in a common housing 12, which in turn is arranged within wafer inspection system 10. In FIG. 3, a time is shown at which the rotary mirror is in a 45° position and first flash source 21 has been triggered. In the operating state shown, the rotary mirror images the light beam coming from the left vertically onto the end of optical waveguide 40.

FIG. 4 shows the arrangement of FIG. 3, wherein the second flash source is triggered instead of the first. The rotary mirror 33 is in a 135° position and vertically images the flashlight beam coming from the right onto the end of optical waveguide 40. The portion of the flash beam projected to the bottom in the figure shown is the same for the case shown in FIG. 3 and FIG. 4. The beam paths of the first flash source 21 and the second flash source 22 are the same downstream of the redirecting optics 30, i.e. downstream of the rotary mirror.

First flash source 21 is triggered by means of the control means (not shown) whenever the rotary mirror is in a position at 45° or 225°, while second flash source 22 is triggered whenever the rotary mirror is in a position at 135° or 315°. The two flash lamps 23 are therefore alternately triggered twice within each full turn of the rotary mirror. There are therefore four identical light flashes impinging on the end of optical waveguide 40 within one full turn of the rotary mirror. As a result an increase in the flashing frequency for a wafer inspection system 10 is achieved while the flashlight intensity remains the same.

Instead of a rotation it is also conceivable to switch the rotary mirror between two positions. When the mirror assumes a suitable position it triggers the flash devices via a synchronization impulse. The mirror can be coated on one or both sides.

What is claimed is:

1. An apparatus for illuminating the surface of a wafer in a wafer inspection system, comprising a first flash source for emitting a first light beam and a second flash source for emitting a second light beam at a maximum frequency, a redirecting optics and a control means, wherein the flash sources are configured for emitting light toward the redirecting optics, the control means alternately triggers the flash sources with a certain frequency; and the redirecting optics redirects the two light beams into a common beam path upstream of the wafer.

2. The apparatus according to claim 1, wherein the frequency of triggering is higher than half the maximum flashing frequency of the flash sources.

3. The apparatus according to claim 1, wherein the redirecting optics comprises a rotary mirror.

4. The apparatus according to claim 3, wherein the rotary mirror is arranged in such a way that depending on each rotary angle, it reflects each first or second light beam into the same beam path.

5. The apparatus according to claim 4, wherein the control means triggers the flash sources as a function of the rotary position of the rotary mirror in such a way that the light beam of each triggered flash source is reflected into the same beam path.

6. The apparatus according to claim 5, wherein the rotary speed of the rotary mirror is sufficiently high so that the frequency of triggering is higher than half the maximum triggering flashing frequency of the flash sources.

7. The apparatus according to claim 1, wherein the common beam path comprises an optical waveguide.

8. The apparatus according to claim 7, wherein the two light beams impinge on the optical waveguide at the same angle.

9. The apparatus according to claim 1, wherein the flash sources and the redirecting optics have a common carrier, in particular a common housing.

10. The apparatus according to claim 9, wherein the flash sources and the redirecting optics are configured as a module.

11. A method of illuminating the surface of a wafer in a wafer inspection system, comprising the steps of:
rotating a rotary mirror so that the beam path of a first flash source is redirected into a common beam path,
triggering the first flash source,
illuminating the surface of the wafer with the light beam of the first flash source for inspecting the wafer,
rotating the rotary mirror so that the beam path of a second flash source is redirected into a common beam path,
triggering the second flash source,
illuminating the surface of the wafer with the light beam of the second flash source for inspecting the wafer.

12. The method according to claim 11, wherein each light beam passes through an optical waveguide before it impinges on the surface of the wafer.
